(19) United States
(12) Patent Application Publication
(10) Pub. No.: US 2016/0042925 A1
(43) Pub. Date: Feb. 11, 2016

(54) BAFFLE AND SUBSTRATE TREATING APPARATUS INCLUDING THE SAME

(71) Applicant: PSK INC., Gyeonggi-do (KR)

(72) Inventor: Seung Kook YANG, Hwaseong-si (KR)

(21) Appl. No.: 14/465,957

(22) Filed: Aug. 22, 2014

(30) Foreign Application Priority Data
Aug. 6, 2014 (KR) 10-2014-0100906

(51) Int. Cl. H01J 37/32

(52) U.S. Cl. CPC H01J 37/32633; H01J 2237/332; H01J 2237/334; H01J 2237/335

(57) ABSTRACT

Provided is a substrate treating apparatus including: a process chamber; a substrate support unit provided to support a substrate within the process chamber; a baffle positioned on the substrate support unit and formed with a plurality of injection holes; and a gas supply unit supplying a gas onto the baffle, wherein the baffle includes a slope region formed at an edge thereof and inclined such that the height of an upper surface thereof increases as it goes to an outer side surface.

### CROSS-REFERENCE TO RELATED APPLICATIONS

This U.S. non-provisional patent application claims priority under 35 U.S.C. §119 of Korean Patent Application No. 10-2014-0100906, filed on Aug. 6, 2014, the entire contents of which are hereby incorporated by reference.

### BACKGROUND OF THE INVENTION

The present invention relates to a substrate treating apparatus, and more particularly, to an apparatus treating a substrate using plasma or a plasma gas.

To fabricate a semiconductor device, various processes, such as deposition, photolithography, etching, ashing, cleaning, polishing, or the like on a semiconductor substrate, such as a wafer are required. Among such processes, many processes, such as deposition, etching, and ashing treat a substrate, such as a wafer, within a chamber using plasma or a gas.

FIG. 1 is a cross-sectional view illustrating a typical substrate treating apparatus using plasma. Referring to FIG. 1, in a typical substrate treating apparatus, a gas injected into the inside of a top lid 12 through a gas supply unit 11 is converted to plasma by a plasma source 13. The plasma generated by the plasma source 13 is supplied onto a substrate 15 through a baffle 14 within the top lid 12.

The plasma arriving on the baffle 14 collides to an edge inner side surface of the baffle 14 or to an inner sidewall of a chamber in a radial direction of the baffle 14. Therefore, vortexes are generated by a sudden change in a flow direction of the plasma. The vortex prevents smooth injection of plasma through injection holes 16.

Also, since the plurality of typical injection holes of the baffle 14 are formed vertically to the radial direction of the baffle 14, particles generated from an upper side of the baffle 14 may be introduced onto the substrate.

### SUMMARY OF THE INVENTION

The present invention provides a baffle and a substrate treating apparatus that allow a gas to be smoothly supplied to a substrate.

The present invention also provides a baffle and a substrate treating apparatus capable of minimizing introduction of a particle onto a substrate.

The objects of the present invention are not limited to the foregoing those, and other objects will be clearly understood to those skilled in the art from the following description.

Embodiments of then present invention provide surface treating apparatuses. The substrate treating apparatuses include: a process chamber; a substrate support unit provided to support a substrate in the process chamber; a baffle disposed over the substrate support unit and formed with a plurality of injection holes; and a gas supply unit supplying a gas onto the baffle, wherein the baffle includes a slope region formed at an edge thereof and inclined such that the height of an upper surface thereof increases as it goes to an outer side surface.

In some embodiments, the slope region may be formed with a slope hole inclined toward the outer side surface of the baffle as it goes down.

In other embodiments, the baffle may further include a convex region formed at a center region thereof and provided with a convex upper surface.

In still other embodiments, the slope of the slope region may be provided in a straight line.

In even other embodiments, the convex region may be provided in singularity, extending from an inner side end of the slope region.

In yet other embodiments, the convex region may be provided in a uniform thickness throughout.

In further embodiments, the convex region may be provided in plurality.

In still further embodiments, the convex region may further include: a first convex region provided in a ring shape having concentricity as viewed from top; and a second convex region positioned at a center of the first convex region and provided in a circular shape as viewed from top.

In even further embodiments, the convex region may include a plurality of convex regions combined to form a matrix shape as viewed from top.

In yet further embodiments, the injection holes in each of the plurality of convex regions may be formed to penetrate in up and down directions.

In much further embodiments, the baffle may be formed at a region between the convex regions of an upper surface thereof with a slit the bottom of which is blocked.

In still much further embodiments, the baffle may be formed at a region between the convex region and the slope region with the slit.

In even much further embodiments, the slope hole may be provided such that a top area is wider than a bottom area.

In other embodiments of the present invention, there are provided baffles. The baffles may formed with a plurality of injection holes, and include a slope region formed at an edge thereof and inclined such that the height of an upper surface thereof increases as it goes to an outer side.

In some embodiments, the slope region may be formed with a slope hole inclined toward the outer side surface of the baffle as it goes down.

In other embodiments, the baffle may further include a convex region formed at a center region thereof and provided with a convex upper surface.

In still other embodiments, the slope of the slope region may be provided in a straight line.

In even other embodiments, the convex region may be provided in singularity, extending from an inner side end of the slope region.

In yet other embodiments, the convex region may be provided in a uniform thickness throughout.

In further embodiments, the convex region may be provided in plurality.

In still further embodiments, the convex region may further include: a first convex region provided in a ring shape having concentricity as viewed from top; and a second convex region positioned at a center of the first convex region and provided in a circular shape as viewed from top.

In even further embodiments, the convex region may include a plurality of convex regions combined to form a matrix shape as viewed from top.

In yet further embodiments, the injection holes in each of the plurality of convex regions may be formed to penetrate in up and down directions.

In much further embodiments, the baffle may be formed at a region between the convex regions of an upper surface thereof with a slit the bottom of which is blocked.

In still much further embodiments, the baffle may be formed at a region between the convex region and the slope region with the slit.

In even much further embodiments, the slope hole may be provided such that a top area is wider than a bottom area.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a cross-sectional view illustrating a typical substrate treating apparatus;

FIG. 2 is a cross-sectional view illustrating a substrate treating apparatus according to an embodiment of the present invention;

FIG. 3 is a plain view of the baffle of FIG. 2 viewed from top;

FIG. 4 is a cross-sectional view illustrating another embodiment of the inclined hole of FIG. 2; and

FIGS. 5 through 9 are views illustrating other embodiments of the baffle of FIG. 2.

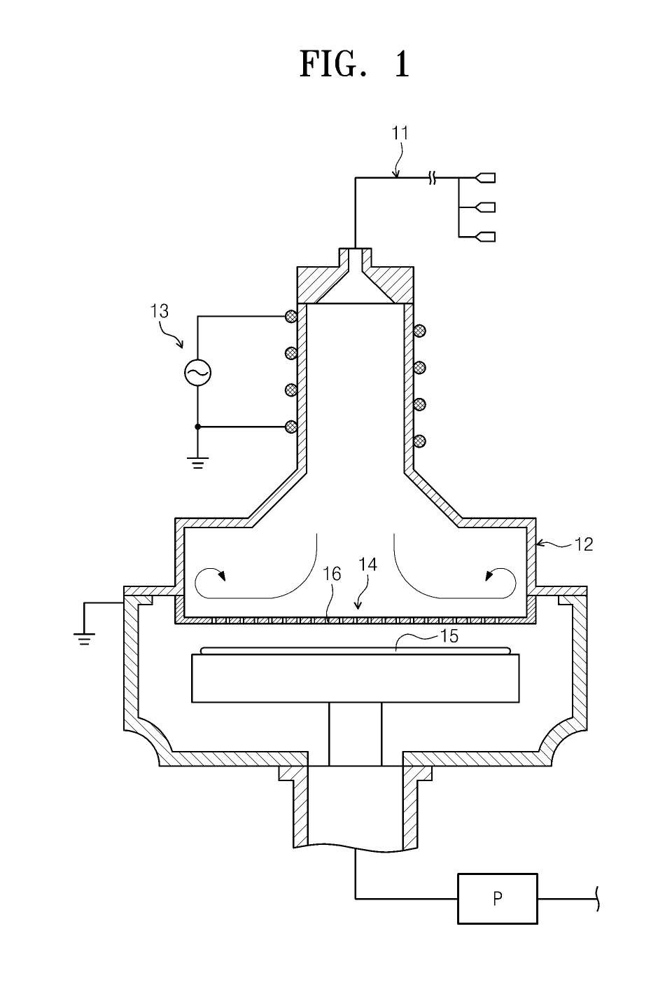

### DETAILED DESCRIPTION OF PREFERRED EMBODIMENTS

Hereinafter, exemplary embodiments will be described in detail with reference to the accompanying drawings. The embodiments of the present invention may be modified in various forms, and the scope of the present invention should not be construed as limited to the following embodiments. These embodiments are provided so that this disclosure will more fully convey the concept of the invention to those skilled in the art. Therefore, the shapes of elements are exaggerated for more clear description.

In embodiments of the present invention, a substrate 10 may be a semiconductor wafer. However, the substrate 10 is not limited thereto and may be a different type of substrate, such as a glass substrate or the like.

Also, in embodiments of the present invention, a substrate treating apparatus may be an apparatus performing a process, for example, ashing, deposition, etching, or the like using plasma or a gas.

Hereinafter, a substrate treating apparatus 1 according to an embodiment of the present invention will be described.

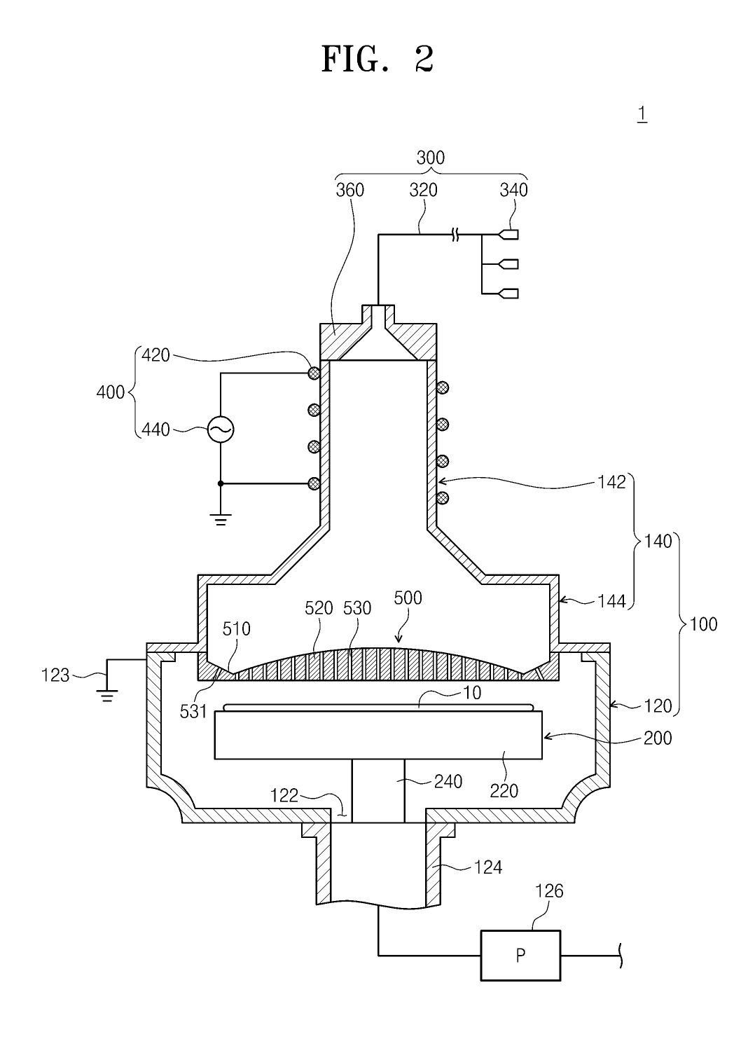

FIG. 2 is a cross-sectional view illustrating a substrate treating apparatus according to an embodiment of the present invention. Referring to FIG. 2, the substrate treating apparatus 1 has a process chamber 100, a substrate support unit 200, a gas supply unit 300, a plasma source 400, and a baffle 500.

The process chamber 100 has a treating room 120 and a plasma generating room 140. The treating room 120 provides a space in which the substrate 10 is treated by plasma. The plasma generating room 140 provides a space in which plasma is generated from a process gas.

The treating room 120 has a space of which top is opened. The treating room 120 may be generally provided in a cylinder shape. The treating room 120 is formed at a sidewall thereof with a substrate inlet (not illustrated). The substrate 10 is loaded into or unloaded from the treating room 120 through the substrate inlet. The substrate inlet (not illustrated) may be opened/closed by an opening/closing member, such as a door (not illustrated). An exhaust hole 122 is formed at a bottom surface of the housing 120. An exhaust line 124 is connected to the exhaust hole 122. A pump 126 is installed on the exhaust line 124. The pump 126 adjusts the pressure in the treating room 120 to a process pressure. A residual gas and a by-product in the treating room 120 are exhausted to the outside of the treating room 120 through the exhaust line 124.

The plasma generating room 140 is positioned outside the treating room 120. In an example, the plasma generating room 140 is positioned on the treating room 120 and is coupled to the treating room 120. The plasma generating room 140 has a discharge room 142 and a diffusion room 144. The discharge room 142 and the diffusion room 144 are sequentially provided in up and down directions. The discharge room 142 has a hollow cylindrical shape. As viewed from top, the space in the discharge room 142 is narrower than that in the treating room 120. Plasma is generated from gases in the discharge room 142. The space in the diffusion room 144 has a portion the width of which increases as it goes down. A lower end of the diffusion room 144 is coupled to an upper end of the treating room 120, and a sealing member (not illustrated) for sealing the diffusion room 144 and the treating room 120 from the outside is provided therebetween.

The process chamber 100 is made of a conductive material. The process chamber 100 may be grounded through a ground line 123.

The substrate support unit 200 supports the substrate 10 within the process chamber 100. The substrate support unit 200 has a support plate 220 and a support shaft 240.

The support plate 220 is positioned within the treating room 120 and is provided in a circular plate shape. The support plate 220 is supported by the support shaft 240. The substrate 10 is placed on the support plate 220. An electrode (not illustrated) is provided within the support plate 220, and the substrate 10 may be supported on the support plate 220 by an electrostatic force or a mechanical clamp.

The gas supply unit 300 supplies a gas onto the baffle 500. The gas supply unit 300 may be provided on the discharge room 142. The gas supply unit 300 may be provided in singularity or plurality. The gas supply unit 300 has a gas supply line 320, a gas storage unit 340, and a gas port 360.

The gas supply line 320 is connected to the gas port 360. The gas port 360 is coupled to an upper side of the discharge room 142. A gas supplied through the gas port 360 is introduced into the discharge room 142 and is then excited to plasma in the discharge room 142.

The plasma source 400 generates plasma in the discharge room 142 from the gas supplied by the gas supply unit 300. In an example, the plasma source 400 may be an inductive coupling plasma source. The plasma source 400 has an antenna 420 and a power supply 440.

The antenna 420 is provided outside the discharge room 142 so as to enclose a side surface of the discharge room 142 two or more times. One end of the antenna 420 is connected to the power supply 440 and the other end is grounded.

The power supply 440 applies power to the antenna 420. In an example, the power supply 440 may apply an RF power to the antenna 420.

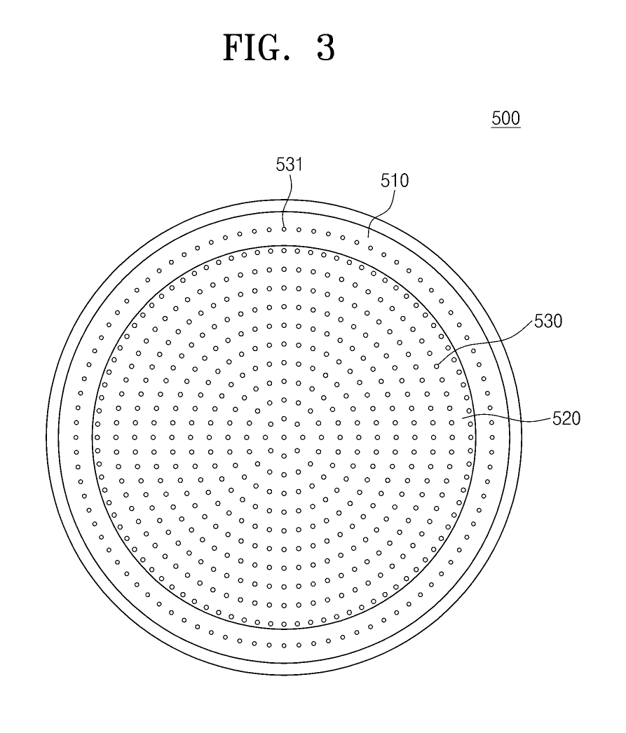

FIG. 3 is a plain view of the baffle of FIG. 2 viewed from top. Referring to FIGS. 2 and 3, the baffle 500 is positioned over the substrate support unit 200. For example, the baffle 500 is provided to a lower end of the diffusion room 144. The plasma is supplied from the diffusion room 144 to the inside of the treating room 120 through injection holes 530. The baffle 500 has a diameter larger than an inner diameter of the lower end of the diffusion room 144. The baffle 500 is grounded. In an example, the baffle 500 may be provided to contact the chamber 100 and thus grounded via the chamber 100. Selectively, the baffle 500 may be directly connected to a separate ground line. The baffle 500 may be provided in a circular shape as viewed from top. The baffle 500 includes a slope region 510 and a convex region 520.

The slope region 510 is formed at an edge region of the baffle 500 The slope region 510 is inclined such that the height of the upper surface thereof increases as it goes to an outer side surface thereof. The slope of the slope region 510 may be provided in a straight line. By doing so, a sudden change in a flow direction of plasma or a gas flowing in the radial direction is alleviated to minimize occurrence of a vortex in flow of plasma or the gas.

The convex region 520 is formed at a central region of the baffle 500. The convex region 520 has a convex upper surface. The convex region 520 is provided in singularity. The convex region 520 is provided extending from an inner side end of the slope region 510. The convex region 520 may be provided such that the thickness thereof increases as it goes to the center thereof. By doing so, the plasma and the gas flow along a curved path of the baffle 500 to make the flow of the plasma and gas smooth. Also, as the area of the upper surface of the baffle 500 increases, heat delivered from the plasma or the like is more widely distributed. Thus, since a temperature difference between the upper surface and a lower surface of the baffle 500 decreases, thermal deformation due to such a temperature difference may be suppressed.

The plurality of injection holes 530 extending from top to bottom of the baffle 500 are formed in the baffle 500. The injection holes 530 may be formed in the same density and same diameter throughout the baffle 500. Alternatively, the injection holes 530 may be formed at different diameters throughout the regions of the baffle 500. The injection holes 530 include slope holes 531. The slope holes 531 are formed in the slope region 510. The slope holes 531 are formed to be inclined toward the outer side surface of the baffle 500 as it goes down. As the slope holes 531 are formed in the slope region 510, particles collected in an edge of the baffle 500 by the flow of the plasma or gas are exhausted toward a side surface of the substrate, thus preventing the particles from being introduced onto the substrate.

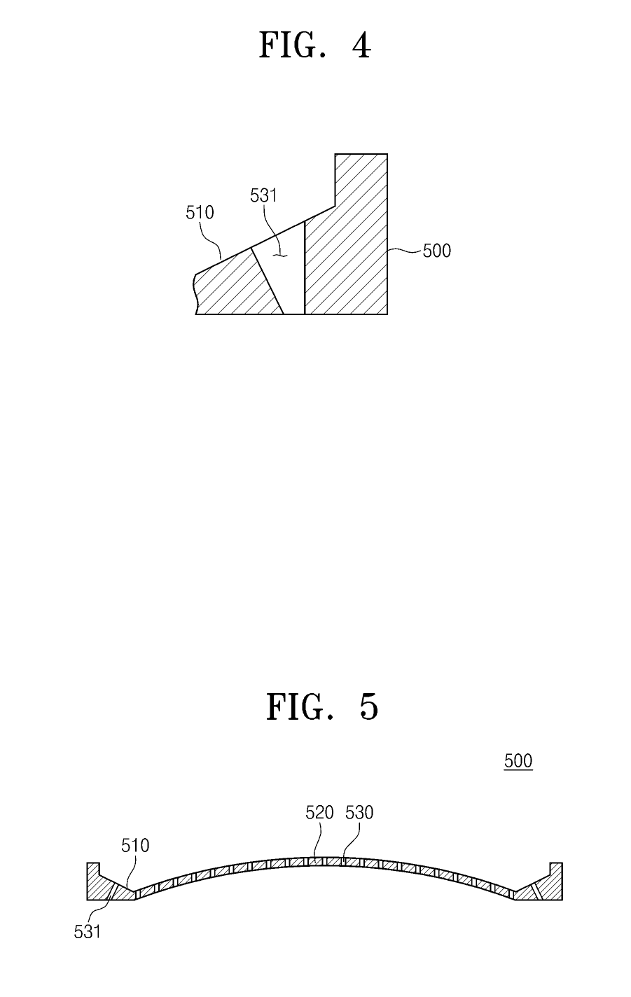

FIG. 4 is a cross-sectional view illustrating another embodiment of the inclined hole of FIG. 2. Referring to FIG. 4, the slope holes 531 may be provided such that an upper area thereof is wider than a lower area. Therefore, the configuration of the slope holes 531 allows particles to be efficiently exhausted to the outer side surface, compared with a case that the upper area of the slope hole 531 is provided to be the same as the lower area.

FIG. 5 is a cross-sectional view illustrating another embodiment of the baffle 500 of FIG. 2. Referring to FIG. 5, the convex region 530 may be provided in a uniform thickness throughout. Other structures, configurations and effects of the baffle 500 in FIG. 5 are similar to those of the baffle 500 in FIG. 2.

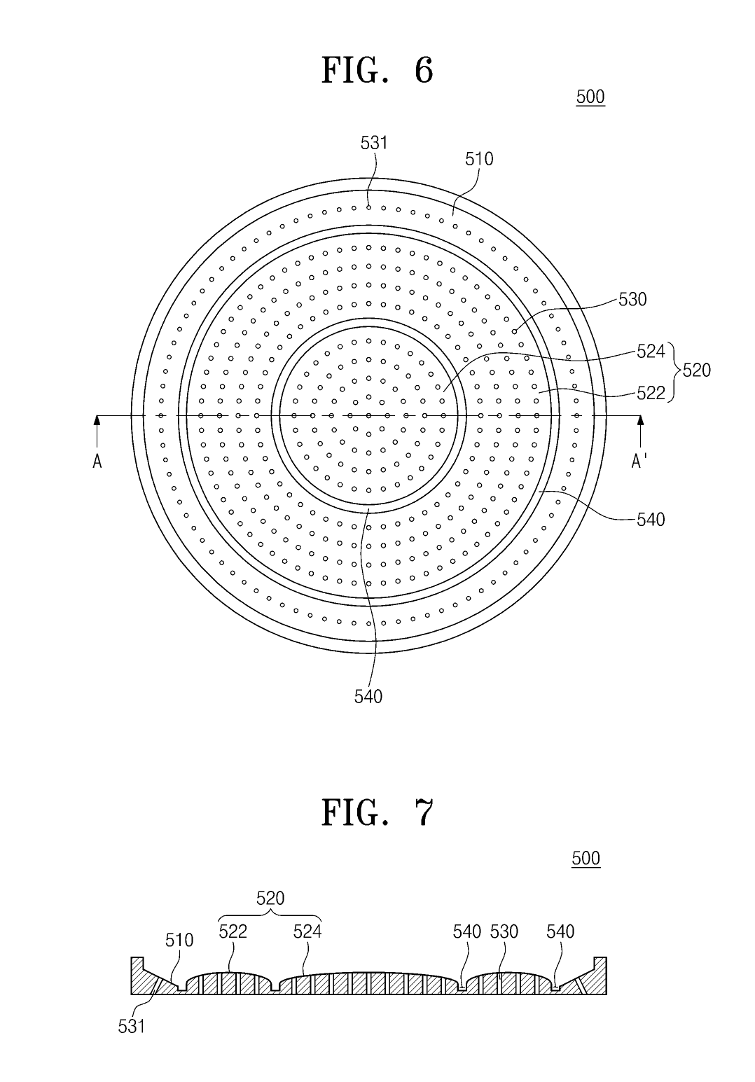

FIG. 6 is a plain view illustrating still another embodiment of the baffle 500 of FIG. 2 viewed from top. FIG. 7 is a cross-sectional view taken along line A-A′ of the baffle 500 of FIG. 6. Referring to FIGS. 6 and 7, a plurality of convex regions 520 are provided. Injection holes in each of the plurality of convex regions 520 are formed to penetrate in up and down directions. The convex region 520 includes a first convex region 522 and a second convex region 524.

As viewed from top, the first convex region 522 is provided in a ring shape. The first convex region 522 may be provided including a plurality of convex regions having different diameters and the same concentricity.

The second convex region 524 is positioned at a center of the first convex region 522 and provided in a circular shape as viewed from top.

The baffle 500 is formed at a region between the convex regions 520 of the upper surface thereof and between the convex region 520 and a slope region 510 with a slit 540 the bottom of which is blocked. In this case, since particles are collected in the slit 540 along flow of plasma or a gas formed along a curved surface of the convex region 520, it may be efficiently prevented that the particles are introduced onto a substrate.

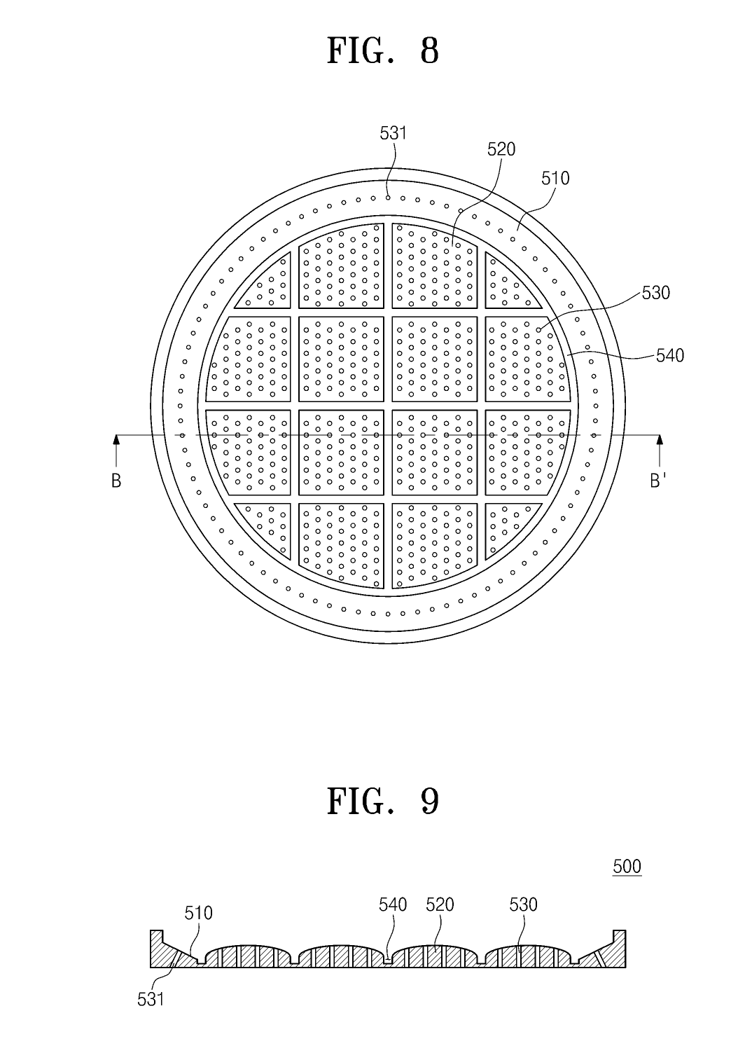

FIG. 8 is a plain view illustrating still another embodiment of the baffle 500 of FIG. 2 viewed from top. FIG. 9 is a cross-sectional view taken along line B-B′ of the baffle 500 of FIG. 8. Referring to FIGS. 8 and 9, as viewed from top, a plurality of convex regions 520 are combined to form a matrix shape. Other structures, configurations and effects of the baffle 500 in FIG. 8 are similar to those of the baffle 500 in FIG. 6.

According to embodiments of the present invention, the baffle and the substrate treating apparatus may smoothly supplies plasma or a gas to a substrate.

Also, the baffle and the substrate treating apparatus may minimize introduction of a particle onto a substrate.

What is claimed is:

1. A substrate treating apparatus comprising:
a process chamber;
a substrate support unit provided to support a substrate within the process chamber;
a baffle positioned over the substrate support unit and formed with a plurality of injection holes; and
a gas supply unit supplying a gas onto the baffle,
wherein the baffle includes a slope region formed at an edge thereof and inclined such that the height of an upper surface thereof increases as it goes to an outer side surface.

2. The substrate treating apparatus of claim 1, wherein the slope region is formed with a slope hole inclined toward an outer side surface of the baffle as it goes down.

3. The substrate treating apparatus of any of claims 1 to 2, wherein the baffle further comprises a convex region formed at a center region thereof and provided with a convex upper surface.

4. The substrate treating apparatus of claim 3, wherein the slope of the slope region is provided in a straight line.

5. The substrate treating apparatus of claim 3, wherein the convex region is provided in singularity.

6. The substrate treating apparatus of claim 5, wherein the convex region is provided extending from an inner side end of the slope region.

7. The substrate treating apparatus of claim 3, wherein the convex region is provided in a uniform thickness throughout.

8. The substrate treating apparatus of claim 3, wherein the convex region is provided in plurality.

9. The substrate treating apparatus of claim 8, wherein the convex region comprises a first convex region provided in a ring shape having concentricity as viewed from top.

10. The substrate treating apparatus of claim 9, wherein the convex region further comprises a second convex region positioned at a center of the first convex region and provided in a circular shape as viewed from top.

11. The substrate treating apparatus of claim 8, wherein the convex region comprises a plurality of convex regions combined to form a matrix shape as viewed from top.

12. The substrate treating apparatus of claim 8, wherein in each of the plurality of convex regions, the injection holes are formed to penetrate in up and down directions.

13. The substrate treating apparatus of claim 8, wherein the baffle is formed at a region between the convex regions of an upper surface thereof with a slit the bottom of which is blocked.

14. The substrate treating apparatus of claim 13, wherein the baffle is formed at a region between the convex region and the slope region with the slit.

15. The substrate treating apparatus of claim 2, wherein the slope hole is provided such that a top area is wider than a bottom area.

16. A baffle formed with a plurality of injection holes and comprising a slope region formed at an edge thereof and inclined such that the height of an upper surface thereof increases as it goes to an outer side surface.

17. The baffle of claim 16, wherein the slope region is formed with a slope hole inclined toward an outer side surface of the baffle as it goes down.

18. The baffle of any of claims 16 to 17, further comprising a convex region formed at a center region thereof and provided with a convex upper surface.

19. The baffle of claim 18, wherein the slope of the slope region is provided in a straight line.

20. The baffle of claim 18, wherein the convex region is provided in singularity.

21. The baffle of claim 20, wherein the convex region is provided extending from an inner side end of the slope region.

22. The baffle of claim 18, wherein the convex region is provided in a uniform thickness throughout.

23. The baffle of claim 18, wherein the convex region is provided in plurality.

24. The baffle of claim 23, wherein the convex region comprises a first convex region provided in a ring shape having concentricity as viewed from top.

25. The baffle of claim 24, wherein the convex region further comprises a second convex region positioned at a center of the first convex region and provided in a circular shape as viewed from top.

26. The baffle of claim 23, wherein the convex region comprises a plurality of convex regions combined to form a matrix shape as viewed from top.

27. The baffle of claim 23, wherein in each of the plurality of convex regions, the injection holes are formed to penetrate in up and down directions.

28. The baffle of claim 23, the baffle is formed at a region between the convex regions of an upper surface thereof with a slit the bottom of which is blocked.

29. The baffle of claim 28, wherein the baffle is formed at a region between the convex region and the slope region with the slit.

30. The baffle of claim 17, wherein the slope hole is provided such that a top area is wider than a bottom area.
